(19) United States
(12) Patent Application Publication
(10) Pub. No.: US 2024/0046133 A1
(43) Pub. Date: Feb. 8, 2024

(54) EXCITONIC BOSE-EINSTEIN CONDENSATE (BEC) AS QUBITS USING SEMICONDUCTOR NANOSTRUCTURES FOR QUANTUM TECHNOLOGIES

(71) Applicant: INDIAN INSTITUTE OF SCIENCE EDUCATION AND RESEARCH, Pune (IN)

(72) Inventors: Shouvik DATTA, Pune (IN); Amit BHUNIA, Pune (IN); Mohamed HENINI, Pune (IN); Maryam Al HUWAYZ, Pune (IN); Mohit Kumar SINGH, Pune (IN)

(21) Appl. No.: 18/258,691

(22) PCT Filed: May 27, 2022
(86) PCT No.: PCT/IB2022/054992

§ 371 Date: Jun. 21, 2023

(30) Foreign Application Priority Data
Jun. 8, 2021 (IN) 202121025498

(51) Int. Cl. G06N 10/40; H03K 17/92

(52) U.S. Cl. CPC G06N 10/40; H03K 17/92; H01L 31/035218

(57) ABSTRACT

The present disclosure provides method and system, which use multiple of excitonic BEC(s) and/or excitonic matter-wave(s) and/or excitonic superfluid(s) as a platform to generate multiple (from a few to even millions or more) long-lived Qubits in any conceivable multi-dimensional hybrid nano structure(s), mostly using semiconductor material(s) and/or device structure(s) at any temperature in between 0-500K, and that can sustain any quantum coherence for a much longer time scales of microseconds or milliseconds or even more, but not limited to these time scales for any conceivable faster device operation(s) as well. The macroscopic quantum states of the generated Qubits are easily controllable with applied voltage(s) (dc and/or ac) and/or electrical power, and/or light beam(s), and are easily integrated with semiconductor fabrication techniques for quicker and wider adaptation of Quantum technologies.

### TECHNICAL FIELD

The present disclosure relates generally to the emerging field of quantum technology. In particular, the present disclosure relates to a system and a method of using Bose-Einstein Condensate (BEC) of excitons (as a bound state of electron-hole pairs within a solid) as Quantum bits (Qubits) with the help of Low-dimensional Nanostructures (mostly semiconductors) for controlling one or more quantum technologies.

### BACKGROUND

Background description includes information that may be useful in understanding the present invention. It is not an admission that any of the information provided herein is prior art or relevant to the presently claimed invention, or that any publication specifically or implicitly referenced is prior art.

Due to miniaturization, classical computing powers or technologies are slowly approaching the quantum limits. So the search is on for viable device platforms that can be used and/or scaled up and/or manufactured to exploit quantum phenomena for applications in futuristic quantum information technology.

Currently, a lot of resources are being devoted to exploring Quantum Technologies all over the world. However, almost all of these existing techniques for exploring Quantum Computation use extremely complicated physical phenomena, which are either really short-lived (around pico-seconds or less) and/or only survives at ultra-low temperatures of millikelvin (10⁻³ K) or microkelvin (10⁻⁶ K) or even lesser.

The existing bottom-up approaches for exploring Quantum Computation involve challenging experimental techniques and/or cumbersome and bulky infrastructures such as atomic or ion traps, ultracold atoms on optical lattices, superconducting Josephson junctions, NV centers in diamonds, and control of single semiconductor quantum dot, and the likes, to control quantum properties of few individual quantum particles as Qubits. However, all these fragile quantum phenomena quickly dissipate and/or decohere the quantum coherence, for instance, in excitonic-polariton BEC that is very short-lived, and thereby restrict the effective number of entangled qubits to a small value and also need sophisticated ultrafast lasers as well as an external, high-finesse, optical microcavity. As a result, none of these techniques can be scaled up practically (or usable within a portable device and/or ready to be manufactured en masse) outside a sophisticated research laboratory.

PCT Application No. WO2019051194A1 discloses extreme photoexcitations using high powered lasers for an optoelectronic device which includes a semiconductor layer having electron-hole liquid at an ambient temperature. This invention may theoretically achieve the condensation of gas-like non interacting free excitons into a strongly correlated liquid-like state (i.e. electron-hole liquid) at ambient temperatures. However, it requires extremely high photo excitation, which makes this invention inefficient and difficult to control within a portable device. In addition, this invention involves complicated semiconductor heterostructures placed within an external, high-finesse, optical microcavity. As a result, the invention cannot be easily scaled up for mass production of miniaturized, portable quantum devices along with the requirements of using high photoexcitations with high powered (0.1 Watt or more), and ultrafast lasers.

United States Patent Application No. US20170199036A1 discloses the use of exciton-polariton superfluid based quantum interference device and quatron-polariton quantum interference device that measure phase differences existing in quasiparticles or matter-wave systems, and the related techniques for their use at room temperatures. These exciton-polaritons are different from simple excitons (electron-hole pair), which are formed when excitons are placed within an external, high-finesse, optical microcavity. Moreover, exciton-polaritons are extremely short-lived and are less stable against dissipation and decoherence. Therefore, such implementations require pico-second (10⁻¹² Sec) or femto-second (10⁻¹⁵ Sec) lasers or the so called ultrafast pulsed lasers to tune their quantum states. Any duration higher than few pico-seconds will be considered as ‘longer duration’ for sake of this invention. As a result, this invention cannot be easily scaled up for mass production of miniaturized, portable quantum devices.

Prior art document titled “Preparation of an exciton condensate of photons on a 53-qubit quantum computer, Lee Ann M. Sager, Scott E. Smart, and David A. Mazziotti, Physical Review Research 2, 043205 (2020)” discloses the use of exciton condensate photons in IBM's Quantum Computer which is based on superconducting qubits working only at few milli-Kelvin(10⁻³ K) temperatures and certainly not ready for miniaturization and portability that can happen if one is able to control and manipulate quantum operations using semiconductor devices which can be fabricated using semiconductor fabrication technologies, which can be easily scaled up.

Another prior art document titled “Quantum computing with exciton-polariton condensates, Sanjib Ghosh & Timothy C. H. Liew, npj Quantum Information volume 6, Article number: 16 (2020)” is a theoretical work on exciton-polaritons which are different from simple excitons (electron-hole pairs) that can be excited within materials/structures with bias or light. Exciton-polaritons are half-matter & half-light quasiparticles, and those need elaborate external, high-finesse, optical microcavity as mentioned in FIG. 1 of that paper. Because of their partly light-like character, exciton-polaritons are very short-lived as well. Therefore, such implementations also require ultrafast pulsed lasers to tune their quantum states. Moreover, this paper only deals with a single qubit only.

Yet another prior art document titled “Byrnes, T., Wen, K. & Yamamoto, Y. Macroscopic quantum computation using Bose-Einstein condensates. Phys. Rev. A 85, 040306 (2012” deals with either atomic systems or short-lived exciton-polaritons within an external, high-finesse, optical microcavity. 2nd paragraph of this paper says “Consider a BEC consisting of bosons with two independent degrees of freedom, such as two hyperfine levels in an atomic BEC or spin polarization states of exciton-polaritons”. This paper only considered theoretical viability in such systems but did not address how they can entangle multiple N qubits operationally and or how they can selectively address each (few) qubits individually within the condensate for quantum operations. Moreover, the issues of miniaturization, device implementation, and portability for technological applications are not clear in this paper.

There is, therefore, a requirement in the art to overcome the above limitations or shortcomings and provide a simple, efficient, and controlled platform that can be used and/or scaled up to generate and/or manufacture long-lived Qubits at reasonably high temperatures to exploit quantum phenomena for applications in quantum information technologies along with miniaturization and portability. These include the fabrication and device operation for Quantum computing, Quantum Registers having efficient quantum error corrections protocols with sufficient redundancy and with improved reliability, the device-level experimental control of Quantum Entanglement in Micro/Nanostructures within an IC chip, device-level experimental control of Rabi oscillation of Macroscopic Quantum state within a miniaturized and portable device for wide spread technological applications, Quantum photonics but not limited to the likes.

Further, there is a requirement in the art to generate robust, long-lived Qubits using any conceivable material and/or structures (mostly semiconductors) at any temperature in between 0-500K, which can even sustain quantum coherence for a much longer time scale (few microseconds or millisecond or even more), and can be easily controlled with bias voltage(s) and/or light beam(s) and/or light spot(s) in that quantum devices.

Further, there is a requirement in the art which can be easily integrated with existing semiconductor fabrication expertise for faster, wider and large scale adaptation and/or manufacture of Quantum Devices for their applications in Quantum Technologies and which can also facilitate miniaturization and portability.

### OBJECTS OF THE PRESENT DISCLOSURE

A general object of the present disclosure is to overcome the above-mentioned limitations, and provide a system and a method of using Bose-Einstein Condensate (BEC) of excitons as Quantum bits (Qubits) with the help of Low-dimensional Nano structures (mostly semiconductors) for controlling various quantum technologies.

An object of the present disclosure is to provide a viable platform that can be used and/or scaled up and/or manufactured to exploit quantum phenomena for applications in futuristic quantum information technology.

An object of the present disclosure is to provide a simple, efficient, and controlled platform that can be used to manufacture long-lived Qubits at reasonably high temperatures to exploit quantum phenomena for applications in quantum information technologies along with miniaturization and portability.

An object of the present disclosure is to provide a system and a method that can be easily scaled up for mass production of miniaturized, portable quantum devices.

An object of the present disclosure is to provide a system and a method that negates the need of using very costly and highly complex equipment including ultrafast pulsed lasers.

### SUMMARY

The present disclosure relates generally to the field of quantum technology. In particular, the present disclosure relates to a method of using any quantum state(s) of excitonic Bose-Einstein Condensate(s) (or BECs) and/or excitonic matter-wave(s) and/or excitonic superfluid(s) as Qubit(s) in low dimensional semiconductor nanostructures for controlling one or more quantum technologies.

According to an aspect, the present disclosure pertains to experimental detection and control of Schrodinger's Cat like macroscopically large, quantum coherent state of a two-component Bose-Einstein condensate of spatially indirect electron-hole pairs or excitons. Said excitons are artificial atom like quasi particles within solids, which may be generated with optical and/or electrical excitations.

In an aspect, achieving BEC within an optoelectronic device may provide access to millions of excitons as qubits to allow efficient, fault-tolerant quantum computation. Moreover, in the present disclosure, phase coherent periodic oscillations in photo generated capacitance may be measured as a function of applied voltage bias and light intensity over a macroscopically large area.

In another aspect, periodic presence and absence of splitting of excitonic peaks in the optical spectra based on photocapacitance may point towards tunnelling induced variations in capacitive coupling between quantum well and quantum dots. Further, observation of negative ‘quantum capacitance’ due to screening of charge carriers by the quantum well may indicate Coulomb correlations of interacting excitons in the plane of the sample.

In another aspect, coherent resonant tunnelling in the well-dot heterostructure may restrict the available momentum space of the charge carriers within the quantum well. Consequently, the average electric polarization vector of the associated indirect excitons collectively can orient along the direction of applied bias and these excitons undergo Bose-Einstein condensation below ˜100 K.

In another aspect, generation of interference beats in photocapacitance oscillation even within coherent white light may further confirm the presence of stable, long range spatial correlation among these indirect excitons.

In another aspect, some of the photo generated excitons may be addressed independently of others using applied bias over alocalized region. In addition, collective Rabi oscillations of the macroscopically large, ‘multipartite’, two-level, coupled and uncoupled quantum states of excitonic condensate as qubits may also be observed.

Therefore, the present disclosure not only brings the physics and technology of Bose-Einstein condensation within the reaches of semiconductor chips, but may also open up experimental investigations of the fundamentals of quantum physics using similar techniques.

In an aspect, operational temperature of such excitonic BEC may be raised further using similar 0D-2D heterostructure having more densely packed, ordered array of QDs in the x-y plane and/or using materials having larger excitonic binding energies. The present disclosure may bring in a paradigm shift in optoelectronics for faster and wider adaptation of quantum technologies in terms of miniaturization and portability.

### BRIEF DESCRIPTION OF DRAWINGS

The accompanying drawings are included to provide a further understanding of the present disclosure, and are incorporated in and constitute a part of the specification(s) mentioned herein. The drawings illustrate exemplary embodiments of the present disclosure and, together with the description, serve to explain the principles of the present disclosure. The diagrams are for illustration only, which thus is not a limitation of the present disclosure.

In the figures, similar components and/or features may have the same reference label. Further, various components of the same type may be distinguished by following the reference label with a second label that distinguishes among the similar components. If only the first reference label is used in the specification, the description is applicable to any one of the similar components having the same first reference label irrespective of the second reference label.

FIG. 1 illustrates an exemplary block diagram of the proposed system in order to elaborate its overall working, in accordance with an embodiment of the present disclosure.

FIG. 2A illustrates an exemplary nanostructured sample used in the proposed system, in accordance with an embodiment of the present disclosure.

FIG. 2B illustrates the representative energy band diagram and formations of the spatially indirect exciton associated with the nanostructured sample, in accordance with an embodiment of the present disclosure.

FIG. 3 illustrates an exemplary flow diagram of the proposed method, in accordance with an embodiment of the present disclosure.

FIGS. 4A and 4B illustrate graphical representation for coherent oscillation of phtotocapacitance response of millions of the excitons, in accordance with an embodiment of the present disclosure.

FIGS. 5A and 5B illustrate representative results demonstrating coherent oscillation of phtotocapacitance response of millions of the excitons, in accordance with an embodiment of the present disclosure.

FIGS. 6A to 6C illustrate the splitting of excitonic transitions in photocapacitance spectra, in accordance with an embodiment of the present disclosure.

FIG. 6D illustrates ‘negative quantum capacitance’, in accordance with an embodiment of the present disclosure.

FIG. 7 illustrates sudden and uncharacteristic enhancement of photocapacitance oscillations from the excitons, in accordance with an embodiment of the present disclosure.

FIG. 8 illustrates observation of quantum interference beats, in accordance with an embodiment of the present disclosure.

FIGS. 9A and 9B illustrate the evidence of excitonic Rabi Oscillation as a function photoexcitation amplitude or ‘time’ in the Low dimensional 0D-2D Nanostructured sample having many (millions) InAs Quantum Dots (QDs), in accordance with an embodiment of the present disclosure.

FIG. 10 illustrates an exemplary schematic depiction of device-level quantum operations using excitonic BEC(s) and/or excitonic matter-wave(s) and/or excitonic superfluid(s), which embodies the present invention.

### DETAILED DESCRIPTIONS

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims.

The present disclosure relates generally to the field of quantum technology. In particular, the present disclosure relates to a method of using any quantum state(s) of excitonic Bose-Einstein Condensate(s) (or BECs) and/or excitonic matter-wave(s) and/or excitonic superfluid(s) as Qubit(s) in low dimensional semiconductor nanostructures for controlling one or more quantum technologies.

According to an aspect, the present disclosure elaborates upon a method or process of using any ‘Macroscopic’ quantum state(s) of BEC(s) of excitons and/or their emergent derivatives as quasiparticles (including exciton-polaritons and the likes) and/or excitonic matter-wave(s) and/or excitonic superfluid(s) as Qubit(s) in low dimensional semiconductor nanostructure for controlling one or more quantum technologies.

According to another aspect, the proposed method achieves experimental control of excitonic BEC(s) and/or excitonic matter-wave(s) and/or excitonic superfluid(s), which automatically allows for long-lived quantum states having relatively lesser decoherence and/or lesser loss of phase correlation and/or having relatively dissipation free physical mechanisms for manipulations and control of any excitonic quantum states and/or Qubit(s) using semiconductor devices which can be easily scaled up.

In an embodiment, the method can involve a step of generating a plurality of excitonic BEC(s) and/or excitonic matter-wave(s) and/or excitonic superfluid(s) having macroscopic quantum states, upon excitation of the semiconductor at a predefined temperature, by at least one of the energy sources. The generated macroscopic quantum states of the plurality of excitonic BEC(s) and/or excitonic matter-wave(s) and/or excitonic superfluid(s) can be used as the Qubits for controlling various quantum technologies. Further, the macroscopic quantum states of the generated plurality of excitonic BEC(s) and/or excitonic matter-wave(s) and/or excitonic superfluid(s) can be controlled by varying any or a combination of the predefined temperature (in between 0-500K), and the predefined attributes of one or more energy sources.

According to another aspect, the present disclosure elaborates upon a system for controlling one or more quantum technologies using excitonic Bose-Einstein Condensate(s) (BEC(s)) and/or excitonic matter-wave(s) and/or excitonic superfluid(s) as Qubits using low dimensional semiconductor nanostructures. The proposed method or system may employ a simpler top-down approach of using the collective phenomenon of multiple and/or millions of excitons as electron-hole bound pairs as Qubits by generating macroscopic quantum states of excitonic BEC(s) and/or excitonic matter-wave(s) and/or excitonic superfluid(s) as a platform to generate long-lived Qubits in any conceivable multi-dimensional hybrid material(s), mostly semiconductor(s), at any temperature in between 0-500K, which can sustain quantum coherence for much longer time scale (˜microsecond or ˜millisecond or more), but not limited to only these timescales for any conceivable faster device operation(s) as well. The macroscopic quantum states of the generated Qubits can be easily controlled with bias voltage(s) and/or light beam(s) and/or light spot(s) and can be easily integrated with semiconductor optoelectronics for faster and wider adaptation in Quantum Technologies.

In an embodiment, the experimental control of excitonic BEC(s) and/or excitonic matter-wave(s) and/or excitonic superfluid(s), automatically allows for coherent control of multiple (from a few to even millions or more) excitons in sync and/or correlated with each other, to be used as Qubits within electronic and/or optoelectronic devices which can be easily scaled up.

In an embodiment, the method and system may involve a semiconductor nanostructure having a predefined multi-dimensional hybrid heterostructure and made of a predefined material(s). Further, the method and system may involve one or more energy sources (Electromagnetic/Optical/Thermal/Mechanical and/or some combinations of these) for driving the Quantum Operations of excitonic BEC(s) and/or excitonic matter-wave(s) and/or excitonic superfluid(s) having predefined attributes adapted to be operatively configured with a semiconductor electronic/optoelectronic device(s).

In an exemplary embodiment, the energy source can be an electrical power source(s) that can generate electrical voltage(s) or electrical power having a predefined (attributes) amplitude, power factor, and frequency, but not limited to the likes.

In an exemplary embodiment, the energy source can be a light source(s) that can generate any or a combination of CW, Pulsed, polarized and/or unpolarized light beam(s) and/or light spot(s), having the predefined attributes comprising sizes, intensities, wavelengths, and modulation frequencies, angular momentum(s), spin(s), helicity(s), but not limited to the likes.

In another exemplary embodiment, the energy source can also be a magnetic power source(s) that can generate a magnetic field or magnetic power having a predefined (attributes) amplitude, power factor, and frequency, but not limited to the likes.

In yet another exemplary embodiment, the energy source can also be a piezoelectric/thermoelectric/thermomagnetic/electromechanical/triboelectric power source(s) that can deliver power having a predefined (attributes) amplitude, power factor, and frequency, but not limited to the likes.

In an implementation, upon energization of the energy source being coupled to the semiconductor, the energy source can excite the semiconductor with electromagnetic energy or light/photons having a specific wavelength and energy, then the semiconductor at the predefined temperature can correspondingly generate multiple excitonic BECs having macroscopic quantum states. The macroscopic quantum states of the generated plurality of excitonic BEC(s) and/or excitonic matter-wave(s) and/or excitonic superfluid(s) can be controlled by varying any or a combination of the predefined temperature (in between 0-500K), and the predefined attributes of the energy sources. Accordingly, the Qubits can sustain quantum coherence for a much longer time scale but not limited to microseconds or milliseconds or more, and the macroscopic Quantum States of the Qubits can be easily controlled with bias voltage(s) and light beam(s) and/or light spot(s) at a temperatures in between 0-500 Kelvin, and even at room temperature, and can be easily integrated with semiconductor electronics and/or optoelectronics fabrication expertise for faster and wider adaptation of Quantum Technologies.

Further, the generated Qubits can facilitate experimental control of the Macroscopic quantum state for device applications in both time and frequency domains.

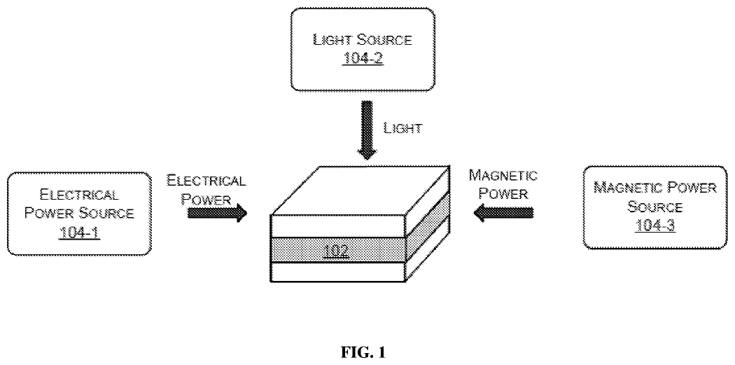

Referring to FIG. 1, the proposed system 100 (also, referred to as system 100, herein) can be configured to control one or more quantum technologies using excitonic Bose-Einstein Condensate (BEC) as Qubits in semiconductors. In an embodiment, the system 100 can include a semiconductor 102 having a predefined multi-dimensional hybrid heterostructure and made of a predefined material. In an exemplary embodiment, the semiconductor 102 can have the predefined multi-dimensional hybrid heterostructure of 0D-2D, which can be made of the predefined material selected from a Group III-V semiconductors. In another exemplary embodiment, the predefined material can have a high excitonic energy and can be selected from any of:
a) Oxides and Nitrides selected from Cu₂O, ZnO, GaN, InN, AlN, and their corresponding alloys, and
b) Transition Metal di-chalcogenides (TMDC) selected from MoS₂, MoSe₂, WS₂, WSe₂, ReS₂, and the likes.

In another embodiment, the system 100 can include one or more energy sources 104 having predefined attributes, where each of the one or more energy sources 104 can be adapted to be operatively configured with the semiconductor 102. In one embodiment, the one or more energy sources 104 can be an electrical power source 104-1, which can generate electrical voltage, where the predefined attributes of the generated electrical voltage can include, but not limited to, amplitude, power factor, and frequency. In an exemplary embodiment, a voltage bias can be utilized as the electrical power source 104-1.

In other embodiment, the one or more energy sources 104 can be a light source 104-2, which can generate a specific light including, but not limited to, any or a combination of Cool white(CW), Pulsed, polarized, and unpolarized light, where the predefined attributes of said light can include spot sizes, intensities, wavelengths, modulation frequencies, and the like. In an exemplary embodiment, a light beam can be utilized as the light source 104-2.

In another embodiment, the one or more energy sources 104 can be a magnetic power source 104-3, which can generate magnetic field/magnetic power, where the predefined attributes of the magnetic power can include, but not limited to, amplitude, power factor, and frequency. In an exemplary embodiment, an electromagnet can be utilized as the magnetic power source 104-3.

In an implementation, at a given time-instant, any of the voltage bias, the light beam, and the electromagnet, can be selected to function as the one or more energy sources 104.

In an embodiment, the semiconductor 102 can be at a predefined temperature, at which upon excitation by at least one of the one or more energy sources 104, the semiconductor 102 can generate a plurality of excitonic BECs or excitonic matter-wave having macroscopic quantum states. In an exemplary embodiment, the predefined temperature can be selected from 0-500K.

Further, the generated macroscopic quantum states of the plurality of excitonic BECs can be used as the Qubits for controlling the one or more quantum technologies in frequency and time domain devices and/or applications, and wherein the macroscopic quantum states of the generated plurality of excitonic BECs or excitonic matter-wave can be controlled by varying any or a combination of the predefined temperature, and the predefined attributes of the one or more energy sources 104. In an exemplary embodiment, the one or more quantum technologies can be selected from Quantum computing, fabrication, device operation of Quantum Registers for efficient quantum error corrections protocols for improved reliability, generation and device-level experimental control of Quantum entanglement in micro/nanostructures within an IC chip, and device-level experimental control of Rabi oscillation of macroscopic Quantum state for technological applications.

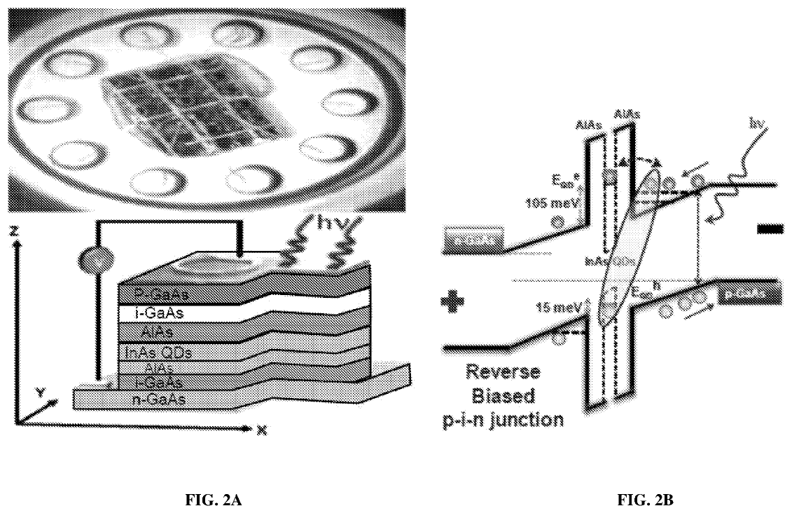

Referring to FIGS. 2A and 2B, the FIG. 2A illustrates an exemplary low dimensional, 0D-2D nanostructured sample also commonly known as ‘double-barrier, resonant tunnelling diode’, which can be utilized as the semiconductor 102 in the proposed system 100. Here, ‘D’ may represent dimension.

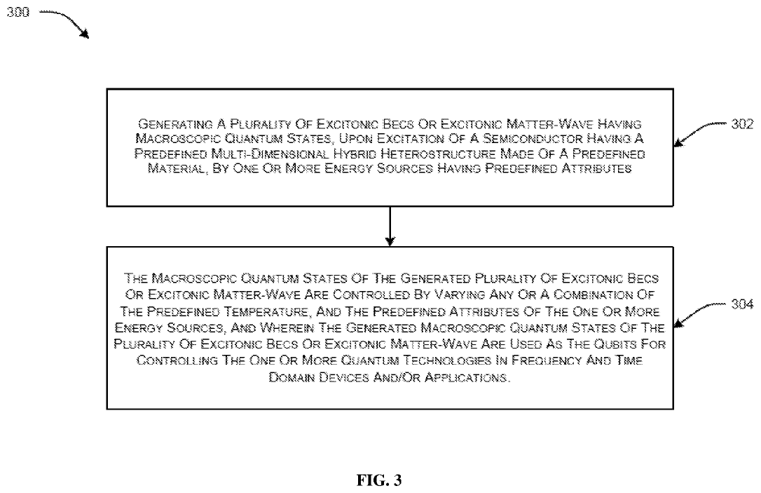

Referring to FIG. 3, the proposed method 300 (also, referred to as method 300, herein) can facilitate usage of excitonic Bose-Einstein Condensate (BEC) as Qubits in semiconductors for controlling one or more quantum technologies.

In an embodiment, the proposed method 300 can include generating, at step 302, a plurality of excitonic BECs or excitonic matter-wave having macroscopic quantum states, upon excitation of a semiconductor having a predefined multi-dimensional hybrid heterostructure made of a predefined material, by one or more energy sources having predefined attributes.

Further, the method 300 can include a step 304, at which the macroscopic quantum states of the plurality of excitonic BECs or excitonic matter-wave, being generated at the step 302, can be controlled by varying any or a combination of the predefined temperature, and the predefined attributes of the one or more energy sources. Moreover, the generated macroscopic quantum states of the plurality of excitonic BECs or excitonic matter-wave can be used as the Qubits for controlling the one or more quantum technologies in frequency and time domain devices and/or applications.

In an embodiment, the one or more energy sources can be selected from any or a combination of an electrical power source, a light source, and a magnetic power source. In one embodiment, the electrical power source, for instance a voltage bias, can generate electrical voltage having the predefined attributes, such as amplitude, power factor, and frequency.

In other embodiment, the light source, for instance a light beam, can generate any or a combination of CW, Pulsed, polarized, and unpolarized light, having the predefined attributes, such as spot sizes, intensities, wavelengths, and modulation frequencies. In another embodiment, the magnetic power source, for instance an electromagnet, can generate magnetic field or magnetic power having the predefined attributes, such as amplitude, power factor, and frequency.

In an embodiment, the semiconductor can have the predefined multi-dimensional hybrid heterostructure of 0D-2D, which can be made of the predefined material selected from a Group III-V semiconductors, where the predefined material can have a high excitonic energy and can be selected from any of: Oxides and Nitrides selected from Cu₂O, ZnO, GaN, InN, AN, and their corresponding alloys, and Transition Metal di-chalcogenides (TMDC) selected from MoS₂, MoSe₂, WS₂, WSe₂, ReS₂, and the likes. Further, the predefined temperature can be selected from 0-500K.

In an embodiment, the method and system may involve a semiconductor nanostructure having a predefined multi-dimensional hybrid heterostructure and made of a predefined material(s). Further, the method and system may involve one or more energy sources (electromagnetic/optical/thermal/mechanical and/or some combinations of these) for driving the Quantum operations of excitonic BEC(s) and/or excitonic matter-wave(s) and/or excitonic superfluid(s) having predefined attributes adapted to be operatively configured with a semiconductor electronic/optoelectronic device(s).

In an exemplary embodiment, the energy source can be an electrical power source(s) that can generate electrical voltage(s) or electrical power having a predefined (attributes) amplitude, power factor, and frequency, but not limited to the likes.

In an exemplary embodiment, the energy source can be a light source(s) that can generate any or a combination of CW, Pulsed, polarized and/or unpolarized light beam(s) and/or light spot(s), having the predefined attributes comprising sizes, intensities, wavelengths, and modulation frequencies, angular momentum(s), spin(s), helicity(s), but not limited to the likes.

In another exemplary embodiment, the energy source can also be a magnetic power source(s) that can generate a magnetic field or magnetic power having a predefined (attributes) amplitude, power factor, and frequency, but not limited to the likes.

In yet another exemplary embodiment, the energy source can also be a piezoelectric/thermoelectric/thermomagnetic/electromechanical/triboelectric power source(s) that can deliver power having a predefined (attributes) amplitude, power factor, and frequency, but not limited to the likes.

In an implementation, upon energization of the energy source being coupled to the semiconductor, the energy source can excite the semiconductor with electromagnetic energy or light/photons having a specific wavelength and energy, then the semiconductor at the predefined temperature can correspondingly generate multiple excitonic BECs having macroscopic quantum states. The macroscopic quantum states of the generated plurality of excitonic BEC(s) and/or excitonicmatter-wave(s) and/or excitonic superfluid(s) can be controlled by varying any or a combination of the predefined temperature (in between 0-500K), and the predefined attributes of the energy sources. Accordingly, the Qubits can sustain quantum coherence for a much longer time scale but not limited to microseconds or milliseconds or more, and the macroscopic Quantum States of the Qubits can be easily controlled with bias voltage(s) and light beam(s) and/or light spot(s) at a temperatures in between 0-500 Kelvin, and even at room temperature, and can be easily integrated with semiconductor electronics and/or optoelectronics fabrication expertise for faster and wider adaptation of Quantum Technologies.

Further, the generated Qubits can facilitate experimental control of the Macroscopic quantum state for device applications in both time and frequency domains.

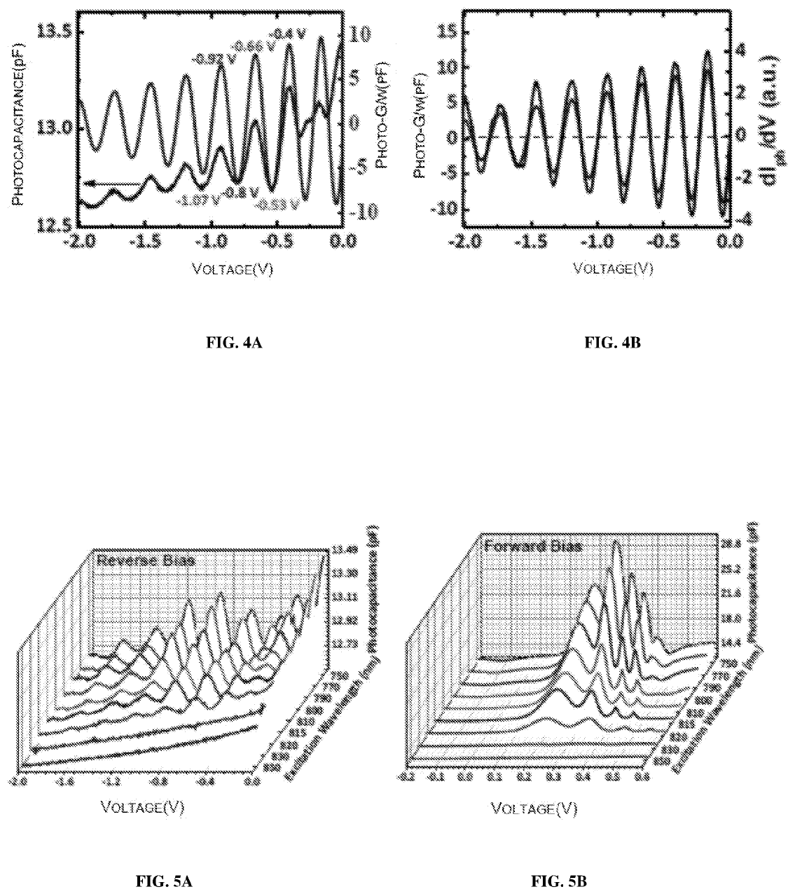

Referring to FIGS. 4A and 4B, coherent oscillation of phtotocapacitance response can be observed for millions of the excitons below the top electrical contact of width ˜0.2 millimeters with bias voltage(s) and light.

Referring to FIGS. 5A and 5B, simulation results demonstrating coherent oscillation of phtotocapacitance response of millions of the excitons below the top electrical contact of width ˜0.2 millimeters with bias voltage(s) and light.

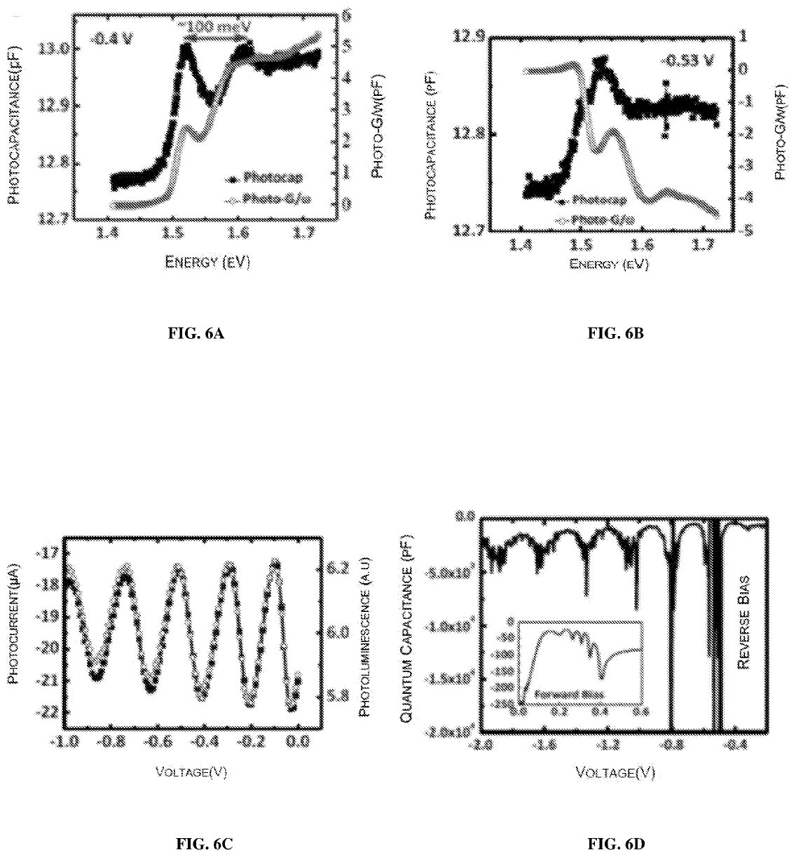

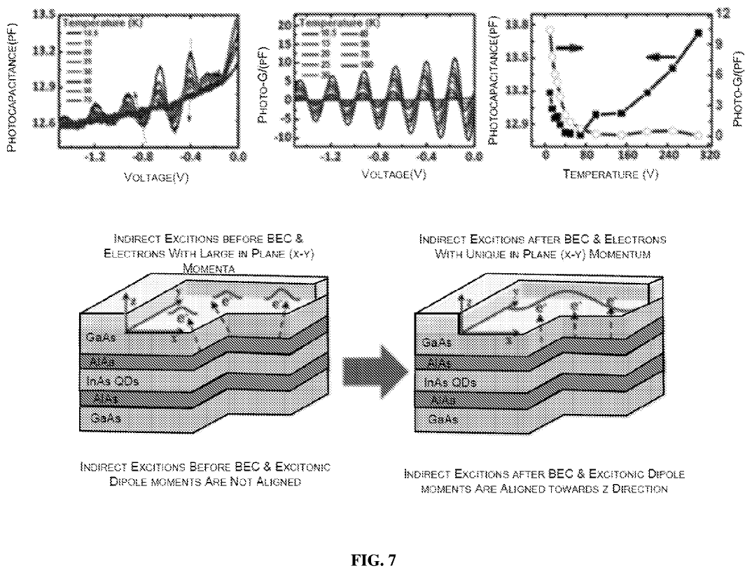

Referring to FIGS. 6A to 6D, the FIGS. 6A and 6B, can illustrate the splitting of excitonic transitions in photocapacitance spectra indicating strong ‘quantum’ coupling in 0D and 2D nanostructure (electron reservoirs) through coherent resonant tunnelling of electrons. This can also be reflected in the FIG. 6C. Further, the FIG. 6D shows ‘negative quantum capacitance’ indicating strong Coulomb correlation in the XY plane as a precursor to the excitonic BEC.

In an embodiment, the present/proposed invention can demonstrate that Hadamard Quantum Gate operation can tune quantum entanglement in such strongly quantum coupled 0D-2D systems as evidenced in the FIGS. 6A-6D. The proposed invention is, however, not just limited to Hadamard Quantum Gate operations. Rather it embodies Hadamard quantum gate operations and all other Universal quantum gate operations using the macroscopic quantum state of excitonic BEC(s) and/or excitonic matter-wave(s) and/or excitonic superfluid(s).

Referring to FIG. 7, sudden and uncharacteristic enhancement of photocapacitance oscillations from the excitons below ˜100 K indicating a BEC-like phase transition collective electric polarization of millions of excitons below the ˜0.2 millimeter wide top electrical contact as illustrated in the FIG. 2A.

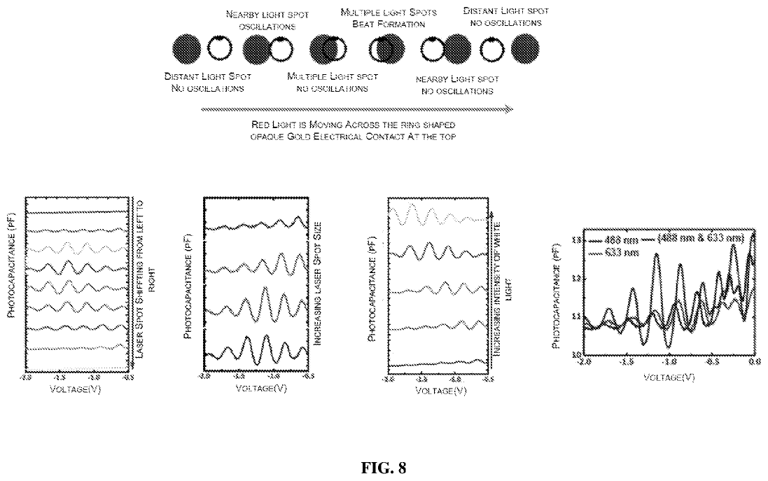

Referring to FIG. 8, observation of quantum interference beats can be an evidence of long-range spatial coherence of excitonic BEC formed by interfering spatially-fragmented light spots across/over a macroscopically large electrical contact of width ˜0.2 millimetre.

In an embodiment, top panel of the FIG. 8 shows the schematic depiction of the movement of laser spot from left to right across the ring-shaped top electrical contact of diameter ˜0.2 mm. Spatially fragmented light spots (red) can interfere around the vicinity of the gold ring (black). The Photocapacitance beats can be formed when two spatially separated, overlapping excitonic ensembles interfere across the gold ring's opaque periphery. Similar beat formation with incoherent white light can be observed, which shows that the long-range phase coherence is not coming from the light source but is generated within the sample indicating excitonic BEC.

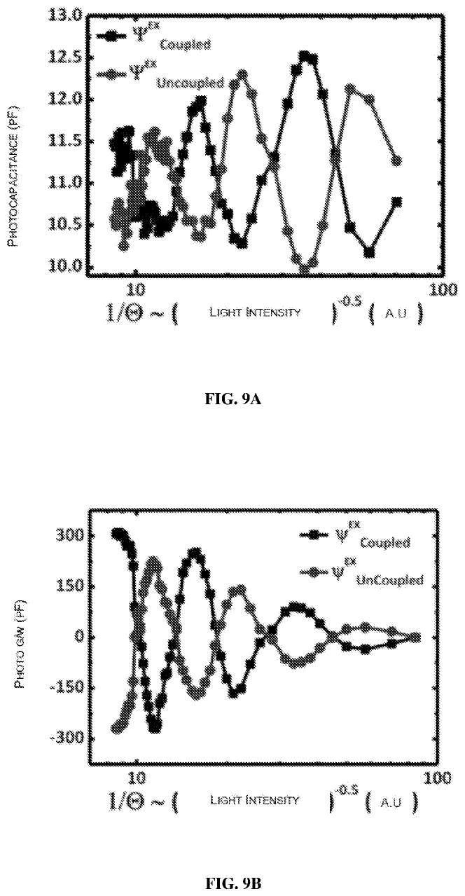

Referring to FIGS. 9A and 9B, the evidence of excitonic Rabi Oscillation can be observed as a function photoexcitation amplitude (electric field of light) or ‘time’ in the Low dimensional 0D-2D Nanostructured sample having many (millions) InAs Quantum Dots (QDs). Millions of excitons may take part in such oscillations below the ˜0.2 millimeter wide top electrical contact. Past works had demonstrated Rabi Oscillations involving single quantum dot and/or single qubit only, whereas through the proposed procedure millions of excitons can take part in the Rabi Oscillations at any given time-instant.

In an embodiment, the FIGS. 9A and 9B illustrate an experimental graph representing Quantum Rabi oscillations of two-level ‘macroscopic’ quantum state of coupled and uncoupled excitons using millions of quantum dots with increasing light intensity or pulse width or as a function of ‘time’ as achieved in the present invention. Such Rabi oscillation of excitons were reported only for single Quantum Dots in the past.

Any prior art document on excitonic Quantum control involved costly ultrafast lasers to observe these quantum dots at picosecond time scales because the quantum coherence dissipates very fast in the prior art technology. Similar with the results achieved using the proposed system or method, the Quantum Rabi oscillation of two-level ‘macroscopic’ quantum state of coupled and uncoupled excitons using millions of quantum dots with increasing light intensity is depicted in the FIGS. 9A and 9B. This can be executed without any elaborate nanofabrication and using semiconductor fabrication technologies due to the formation of relatively dissipation free and/or decoherence free excitonic BEC(s) and/or excitonic matter-wave(s) and/or excitonic superfluid(s). Based on the above, a person skilled in the art would be appreciated that the quantum coherence achieved by the present invention can sustain up to microseconds or milliseconds or even more but not limited to these for any conceivable faster device operation(s) as well.

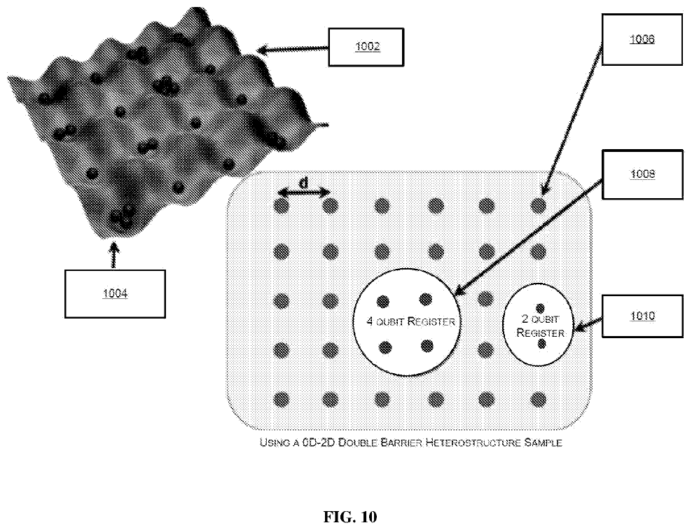

Referring to FIG. 10, the experimental control of excitonic BEC(s) and/or excitonic matter-wave(s) and/or excitonic superfluid(s) automatically allows for coherent control of multiple (from a few to even millions or more) excitonic Qubits demonstrating really robust and long-range spatial coherence or correlations to be used and accessed in quantum device applications.

In an embodiment, a schematic representation of excitonic BEC state as (ψ_{Coupled}^{EX})ⁿ^{₁}⊗(ψ_{Coupled}^{EX})ⁿ^{₂}⊗ . . . (ψ_{Coupled}^{EX})ⁿ^{_{N}} using a 0D-2D heterostructure within a light spot is shown in the top left corner of the FIG. 10.

In one embodiment, a potential energy landscape can be generated, at block 1002, due to Coulomb correlation energy and formation of 0D-2D excitons undergoing exictonic BEC. In other embodiment, at block 1004, excitonic superfluid can be there within 2D checkerboard array around InAs QDs below each electrical contact pads.

In another embodiment, another schematic of a N-qubit register having N numbers of electrical contact pads is depicted down in the FIG. 10. This can also be configured as (ψ_{Coupled}^{EX})ⁿ^{₁}⊗(ψ_{Coupled}^{EX})ⁿ^{₂}⊗ . . . (ψ_{Coupled}^{EX})ⁿ^{_{N}} etc. when multiple light spots overlap and the 0D-2D structure is maximally quantum coupled below some pads and not coupled in the other pads using locally different applied biases and light intensities.

In one embodiment, black-coloured balls represent niexcitons within the 2D ‘checkerboard’ like potential below the i^{th} contact pad. Shapes, sizes and overall design of the array of electrical contact pads and the distance ‘d’ between two neighboring pads can be customized using micro/nano lithography for different quantum applications.

In an embodiment, block 1006 represents semi-transparent electrical contact pad that can be configured to control Rabi oscillations of ψ_{Coupled} and ψ_{Uncoupled} through coherent resonant tunnelling via ac or dc bias.

In an embodiment, block 1008 represents a light spot (CW/pulsed), which can couple ‘N’ excitonic Qubits below neighbouring contact pads via BEC. Ideally, ‘N’ can be very large.

In another embodiment, block 1010 represents another light spot having different wavelength and/or modulation frequency and/or polarization and/or angular momentum. In an exemplary embodiment, such light spots can be overlapping as well.

In an exemplary embodiment, the semiconductor nanostructure used to demonstrate the invention can be a 0D-2D heterostructure of Group III-V semiconductors but not limited to only 0D-2D heterostructures. All prior arts/literature related with similar excitonic BEC(s) and/or excitonic matter-wave(s) and/or excitonic superfluid(s), however, used only planar 2D structures.

According to an aspect, experimental control of excitonic BEC(s) and/or excitonic matter-wave(s) and/or excitonic superfluid(s) up to temperature ˜100 K allows for manipulations and control of quantum states and/or Qubits using semiconductor devices which can be scaled up and/or manufactured with/without using Liquid Nitrogen based Cryogenic technology which are already in use for some commercial Supercomputers, but not limited to the likes.

In a further embodiment, the present disclosure claims any such use of similar multi-dimensional, hybrid heterostructure(s) using any two or more conceivable material(s) (mostly semiconductor(s)) where excitonic BEC(s) and/or excitonic matter-wave(s) and/or excitonic superfluid(s) and/or their emergent derivatives as quasi particles (including exciton-polarilons and the likes) can be used to generate and control macroscopic Qubits for Quantum Computing.

However, similar methods/processes can be extended to room temperature and above using similar 0D-2D Nanostructures using a predefined material(s) (but not limited to only semiconductors) having sufficiently high excitonic binding energy. Such material(s), for the semiconductor(s), can be selected from any of the Group IV and III-V semiconductors, Oxides like Cu₂O, ZnO, Nitrides like GaN, InN, AN and their corresponding alloys and Transition Metal di-chalcogenides (TMDC) selected from MoS₂, MoSe₂, WS₂, WSe₂, ReS₂, as well as any combinations of these materials, and the likes.

In addition, it is to be appreciated by a person skilled in the art that the proposed method or system neither requires nor excludes the use of any sophisticated Micro/Nanolithography to create single isolated quantum dots and/or low dimensional nanostructures for experimental control of quantum state of excitons, as used in the device fabrication technologies or art.

In an embodiment, the proposed system and method generating the long-lived Qubits can be used to exploit quantum phenomena for applications in quantum information technologies including fabrication, and device operation of Quantum computing, Quantum Registers for efficient quantum error corrections protocols for improved reliability, Quantum sources for Quantum Internet as well as generation and device-level experimental control of Quantum Entanglement in Micro/Nanostructures within an IC chip, device-level experimental control of Rabi oscillation of Macroscopic Quantum state of excitons and/or their emergent derivatives as quasiparticles (including exciton-polaritons and the likes) for technological applications, but not limited to the likes.

In another implementation, as proposed method or system generates excitonic BEC(s) and/or excitonicmatter wave(s) and/or excitonic superfluid(s) using a 0D-2D hybrid heterostructure of III-V semiconductors. The proposed method or system can easily be upscaled using semiconductor electronics and/or optoelectronics fabrication methods which can be upscaled for mass production of quantum devices, miniaturised and/or otherwise. Therefore, the present invention is capable of use in multi-dimensional heterostructure(s) using any conceivable material(s) (mostly semiconductor(s)), where excitonic BEC(s) and/or excitonic matter-wave(s) and/or excitonic superfluid(s) can be used to generate and control Qubits for Quantum Computing.

In an embodiment, the proposed method or system can generate and control the macroscopic quantum state of BEC(s) and/or excitonic matter-wave(s) and/or excitonic superfluid(s) of long-lived, spatially indirect excitons. It is to be appreciated by a person skilled in the art that as excitonic BEC(s) of long-lived, spatially indirect excitons encounters relatively less dissipation even in presence of a few or many or even millions of quantum dots hosting correspondingly large number of excitons. So, quantum coherence can sustain for much longer time scales to be used for controlling such quantum devices using semiconductor fabrication technologies, unlike, existing technologies employing exciton-polarilon BEC, as it is not immediately possible with exciton-polariton BEC which are usually very short-lived phenomena.

In an implementation, Quantum entanglement can be tuned and modulated using applied voltage(s) (dc and/or ac) and light beam(s) (both CW &/or Pulsed, polarized, and/or unpolarized) and/or light spot(s) of different sizes, intensities, wavelengths, and modulation frequencies, as suggested in the above paragraphs.

In another implementation, this invention covers the use of excitonic BEC(s) and/or excitonic matter-wave(s) and/or excitonic superfluid(s) using Low dimensional semiconductor nanostructures for Quantum Technologies in both frequency and time domain devices/applications.

In another implementation, the proposed invention can be implemented in Quantum registers for fabrication and device operation of any Quantum Register of many Qubits(multiple and/or millions or more) which can be fabricated as a multi-dimensional array using multi-dimensional heterostructure(s) of any conceivable material(s) (mostly semiconductor(s)). Such Quantum entanglements of many qubits were not yet achieved in the art and were known to be an extremely difficult task.

Further, the quantum registers having many Qubits can also be controlled using applied voltage(s) (dc and/or ac) and light beam(s) (both CW &/or Pulsed, polarized, and/or unpolarized) and/or light spot(s) of different sizes, intensities, wavelengths, and modulation frequencies, as suggested in the above paragraphs.

In yet another implementation, the set of excitonic BEC(s) and/or excitonic matter-wave(s) and/or excitonic superfluid(s) of many entangled Qubits as achieved by the proposed method or system can be implemented in any Quantum Error Correction protocols for reliable quantum computation as a result of sufficient redundancy of having the luxury of dealing with multiple (from a few to even millions or more) Qubits in one single quantum state.

In another implementation, the proposed method or system can be used in the generation and the device-level experimental control of quantum entanglement of microstructure(s)/nanostructure(s) within an IC chip using applied voltage(s) (dc and/or ac) and light beam(s) (both CW &/or Pulsed, polarized and/or unpolarized) and/or light spot(s) of different sizes, intensities, wavelengths, and modulation frequencies, unlike existing technologies where all the individual components of an IC chip work separately as classically individual units.

In comparison with any methods/processes described in any prior art, the present disclosure specifically deals with any Macroscopic Quantum Stale of excitonic BEC(s) and/or excitonic matter-wave(s) and/or excitonic superfluid(s) of long-lived, spatially indirect excitons where electrons and holes of that excitons reside in two different layers and/or materials.

None of thecited background arts demonstrated Device Level Experimental control of millions of Excitons as Qubits, as achieved in the present invention.

None of those background arts demonstrated Quantum Gate Operations using Macroscopic Quantum State of Excitonic BEC using bias voltage(s) and lightbeam(s) and/or light spot(s), as achieved in the present invention.

None of those background arts demonstrated Quantum Gate Operations using Macroscopic Quantum State of excitonic BEC(s) and/or excitonic matter-wave(s) and/or excitonic superfluid(s) using 0D-2D hybrid Nanostructures, as achieved in the present invention.

Excitonic BEC of long-lived, spatially indirect excitonsand the likesencounter relatively less dissipation even in presence of few or even millions of quantum dots and a correspondingly large number of excitons. So (wherein) quantum coherence can sustain for much longer time scales to be used for controlling such quantum devices using semiconductor fabrication technologies. This is not immediately possible with exciton-polariton BEC which are very short-lived phenomena.

Following the present invention, Quantum control of Qubits can be easily up-scaled using semiconductor materials and device fabrication technologies.

The present disclosure claims generation and device-level experimental control of quantum entanglement of micro/nanostructures within an IC chip using applied voltage(s) (dc and/or ac) and light beam(s) (both CW &/or Pulsed, polarized and/or unpolarized) and/or lightspot(s) of different sizes, intensities, wavelengths, and modulation frequencies. Currently, all the individual components of an IC chip work separately as classically individual units.

The present disclosure also claims to bridge the gap between futuristic technologies of quantum computation and optical computation using the tools of electronics and/or opto-electronics Technologies as well as semiconductor materials growth and device fabrication technologies for mass production of next generation quantum devices.

While the foregoing describes various embodiments of the invention, other and further embodiments of the invention may be devised without departing from the basic scope thereof. The scope of the invention is determined by the claims that follow. The invention is not limited to the described embodiments, versions or examples, which are included to enable a person having ordinary skill in the art to make and use the invention when combined with information and knowledge available to the person having ordinary skill in the art.

### Advantages of the Present Disclosure

The present disclosure provides a system and a method of using Bose-Einstein Condensate (BEC) of excitons as Quantum bits (Qubits) with the help of Low-dimensional Nanostructures (mostly semiconductors) for controlling various quantum technologies.

The present disclosure provides a viable platform that can be used and/or scaled up and/or manufactured to exploit quantum phenomena for applications in futuristic quantum information technology.

The present disclosure provides a simple, efficient, and controlled platform that can be used to manufacture long-lived Qubits at reasonably high temperatures to exploit quantum phenomena for applications in quantum information technologies along with miniaturization and portability.

The present disclosure provides a system and a method that can be easily scaled up for mass production of miniaturized, portable quantum devices.

The present disclosure provides a system and a method that negates the need of using very costly and highly complex equipment including ultrafast pulsed lasers.

We claim:

1. A method (300) of using excitonic Bose-Einstein Condensate (BEC) as Qubits in semiconductors for controlling one or more quantum technologies, the method (300) comprising the step:
generating (302) a plurality of excitonic BECs or excitonic matter-wave having macroscopic quantum states, upon excitation of a semiconductor having a predefined multi-dimensional hybrid heterostructure made of a predefined material, by one or more energy sources having predefined attributes,
wherein the macroscopic quantum states of the generated plurality of excitonic BECs or excitonic matter-wave are controlled (304) by varying any or a combination of the predefined temperature, and the predefined attributes of the one or more energy sources, and wherein the generated macroscopic quantum states of the plurality of excitonic BECs or excitonic matter-wave are used as the Qubits for controlling the one or more quantum technologies in frequency and time domain devices and/or applications.

2. A system (100) for controlling one or more quantum technologies using excitonic Bose-Einstein Condensate (BEC) as Qubits in semiconductors, the system (100) comprising:
a semiconductor (102) having a predefined multi-dimensional hybrid heterostructure and made of a predefined material,
one or more energy sources (104) having predefined attributes adapted to be operatively configured with the semiconductor (102), wherein the semiconductor (102) at a predefined temperature, upon excitation by at least one of the one or more energy sources (104), generates a plurality of excitonic BECs or excitonic matter-wave having macroscopic quantum states,
wherein the generated macroscopic quantum states of the plurality of excitonic BECs are used as the Qubits for controlling the one or more quantum technologies in frequency and time domain devices and/or applications, and
wherein the macroscopic quantum states of the generated plurality of excitonic BECs or excitonic matter-wave are controlled by varying any or a combination of the predefined temperature, and the predefined attributes of the one or more energy sources (104).

3. The system (100) as claimed in claim 2, wherein the one or more energy sources (104) is an electrical power source (104-1) that generates electrical voltage having the predefined attributes comprising amplitude, power factor, and frequency.

4. The system (100) as claimed in claim 2, wherein the one or more energy sources (104) is a light source (104-2) that generates any or a combination of CW, Pulsed, polarized, and unpolarized light, having the predefined attributes comprising spot sizes, intensities, wavelengths and modulation frequencies.

5. The system (100) as claimed in claim 2, wherein the one or more energy sources (104) is a magnetic power source (104-3) that generates magnetic field or magnetic power having the predefined attributes comprising amplitude, power factor, and frequency.

6. The system (100) as claimed in claim 2, wherein the one or more energy sources (104) is selected from a voltage bias, a light beam, and an electromagnet.

7. The system (100) as claimed in claim 2, wherein the semiconductor (102) is having the predefined multi-dimensional hybrid heterostructure of 0D-2D, which is made of the predefined material selected from a Group III-V semiconductors.

8. The system (100) as claimed in claim 2, wherein the predefined material is having a high excitonic energy and is selected from any of:
Oxides and Nitrides selected from Cu₂O, ZnO, GaN, InN, AN, and their corresponding alloys, and
Transition Metal di-chalcogenides (TMDC) selected from MoS₂, MoSe₂, WS₂, WSe₂, and ReS₂.

9. The system (100) as claimed in claim 2, wherein the predefined temperature is selected from 0-500K.

10. The system (100) as claimed in claim 2, wherein the one or more quantum technologies is selected from Quantum computing, fabrication, device operation of Quantum Registers for efficient quantum error corrections protocols for improved reliability, generation and device-level experimental control of Quantum entanglement in micro/nanostructures within an IC chip, and device-level experimental control of Rabi oscillation of Macroscopic Quantum state for technological applications.
